(19) United States
(12) Patent Application Publication
(10) Pub. No.: US 2019/0348292 A1
(43) Pub. Date: Nov. 14, 2019

(54) TRANSFERRING EUV RESIST PATTERN TO ELIMINATE PATTERN TRANSFER DEFECTIVITY

(71) Applicant: INTERNATIONAL BUSINESS MACHINES CORPORATION, Armonk, NY (US)

(72) Inventors: Ashim Dutta, Menands, NY (US); Yongan Xu, Niskayuna, NY (US); Ekmini A. De Silva, Slingerlands, NY (US)

(21) Appl. No.: 15/976,285

(22) Filed: May 10, 2018

(51) Int. Cl. H01L 21/308; H01L 21/027; H01L 21/311; G03F 7/09; G03F 7/20

(52) U.S. Cl. CPC H01L 21/3081; H01L 21/0274; H01L 21/3086; G03F 7/2002; G03F 7/094; G03F 7/091; H01L 21/31144

(57) ABSTRACT

A method is presented for transferring patterns to underlying films in patterning stacks. The method includes forming a lithographic stack over a hard mask stack, forming a photoresist layer over the lithographic stack, depositing a conductive cap over the photoresist layer, depositing an organic gap filling material over the conductive cap, and recessing the organic gap filling material to expose top surfaces of the conductive cap. The method further includes etching the exposed top surfaces of the conductive cap to expose top surfaces of the photoresist layer, removing the photoresist layer such that conductive cap sections remain over the lithographic stack, and forming trenches into the lithographic stack and the hard mask stack by using the conductive cap sections as a mask.

### BACKGROUND

### Technical Field

The present invention relates generally to semiconductor devices, and more specifically, to transferring an extreme ultraviolet (EUV) resist pattern to eliminate pattern transfer defectivity.

### Description of the Related Art

In material processing methodologies, pattern etching includes the application of a layer of radiation-sensitive material, such as photoresist, to an upper surface of a substrate, the formation of a pattern in the layer of radiation-sensitive material using photolithography, and the transfer of the pattern formed in the layer of radiation-sensitive material to an underlying thin film on the substrate using an etching process. The patterning of the radiation-sensitive material generally involves exposure of the radiation-sensitive material to a pattern of electromagnetic (EM) radiation using, for example, a photolithography system, followed by removal of irradiated regions of the radiation-sensitive material (as in the case of positive tone resist), or non-irradiated regions (as in the case of negative tone resist) using a developing solution.

### SUMMARY

In accordance with an embodiment, a method is provided for transferring patterns to underlying films in patterning stacks. The method includes forming a lithographic stack over a hard mask stack, forming a photoresist layer over the lithographic stack, depositing a conductive cap over the photoresist layer, depositing an organic gap filling material over the conductive cap, recessing the organic gap filling material to expose top surfaces of the conductive cap, etching the exposed top surfaces of the conductive cap to expose top surfaces of the photoresist layer, removing the photoresist layer such that conductive cap sections remain over the lithographic stack and forming trenches into the lithographic stack and the hard mask stack by using the conductive cap sections as a mask.

In accordance with another embodiment, a method is provided for eliminating patterning defects caused by resist scumming and resist thinning while transferring an extreme ultraviolet (EUV) resist pattern. The method includes forming a photoresist layer over a lithographic stack and a hard mask stack, performing tone inversion by depositing a conductive cap and an organic gap filling material over the photoresist layer, recessing the organic gap filling material to expose top surfaces of the conductive cap, etching the exposed top surfaces of the conductive cap, removing the photoresist layer such that conductive cap sections remain over the lithographic stack, and using the conductive cap sections as a mask to form trenches into the lithographic stack and the hard mask stack.

In accordance with yet another embodiment, a method is presented for eliminating patterning defects caused by resist scumming and resist thinning while transferring an extreme ultraviolet (EUV) resist pattern. The method includes forming an organic planarization layer, forming an anti-reflective coating layer over the organic planarization layer, forming a photoresist layer over the anti-reflective coating layer, performing tone inversion by depositing a conductive cap and an organic gap filling material over the photoresist layer, etching exposed top surfaces of the conductive cap after recessing the organic gap filling material, removing the photoresist layer, and using remaining conductive cap sections as a mask to form trenches into at least the anti-reflective coating layer and the organic planarization layer.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE SEVERAL VIEWS OF THE DRAWINGS

The invention will provide details in the following description of preferred embodiments with reference to the following figures wherein:

FIG. 1 is a cross-sectional view of a semiconductor structure illustrating photoresist portions experiencing resist scumming and local thinning, in accordance with an embodiment of the present invention;

FIG. 2 is a cross-sectional view of the semiconductor structure of FIG. 1 where a conductive cap is deposited over the photoresist, in accordance with an embodiment of the present invention;

FIG. 3 is a cross-sectional view of the semiconductor structure of FIG. 2 where an organic gap fill material is deposited over the conductive cap, in accordance with an embodiment of the present invention;

FIG. 4 is a cross-sectional view of the semiconductor structure of FIG. 3 where the organic gap fill material is recessed by a first amount to expose a top surface of the conductive cap where photoresist portions are affected by resist scumming and resist thinning, in accordance with an embodiment of the present invention;

FIG. 5 is a cross-sectional view of the semiconductor structure of FIG. 4 where the organic gap fill material is recessed by a second amount to expose a top surface of the conductive cap of a photoresist portion experiencing local resist thinning, in accordance with an embodiment of the present invention;

FIG. 6 is a cross-sectional view of the semiconductor structure of FIG. 5 where further etching results in top surfaces of the photoresist being exposed, in accordance with an embodiment of the present invention;

FIG. 7 is a cross-sectional view of the semiconductor structure of FIG. 6 where the photoresist is removed, in accordance with an embodiment of the present invention;

FIG. 8 is a cross-sectional view of the semiconductor structure of FIG. 7 where etching takes place between the remaining conductive cap sections to expose a top surface of a dielectric layer, in accordance with an embodiment of the present invention; and

FIG. 9 is a cross-sectional view of the semiconductor structure of FIG. 8 where a pattern transfer occurs to underlying films, in accordance with an embodiment of the present invention.

Throughout the drawings, same or similar reference numerals represent the same or similar elements.

### DETAILED DESCRIPTION

Embodiments in accordance with the present invention provide methods and devices for transferring patterns effectively by employing extreme ultraviolet (EUV) resist to prevent limitations posed by resist thickness, resist scumming, and resist thinning. The manufacturing of semiconductor devices is dependent upon the accurate replication of computer aided design (CAD) generated patterns onto the surface of the device substrate. The replication process is usually performed by employing lithographic processes, followed by a variety of subtractive (etch) and additive (deposition) processes. More particularly, a photolithography process usually includes applying a layer of photoresist material (e.g., a material that will react when exposed to light), and then selectively exposing portions of the photoresist to light or other ionizing radiation (e.g., ultraviolet, electron beams, X-rays, etc.), thereby changing the solubility of portions of the material. The resist is then developed by washing the resist with a developer solution, such as tetramethylammonium hydroxide (TMAH), thereby removing non-irradiated (in a negative resist) or irradiated (in a positive resist) portions of the resist layer. However, EUV resist thickness for transferring patterns to underlying films and patterning stacks can cause resist scumming and local thinning of the resist line, which can further cause line breaks and line bridges.

Embodiments in accordance with the present invention provide methods and devices for eliminating or significantly reducing resist scumming and resist thinning concurrently or at the same time (as well as preventing line breaks and line bridges) by employing a thin conformal coating or film to the resist to enable tone inversion. The use of the thin conformal coating or film prevents complete filling of recesses by the thin conformal coating or film in the region where the resist thinning occurs. This helps eliminate line break defects during pattern transfer.

Embodiments in accordance with the present invention provide methods and devices for transferring patterns effectively by depositing a thin etch resistant cap material over EUV resist for encapsulation. This cap material can be high-k metal oxide or nitride films deposited using, e.g., atomic layer deposition (ALD) or similar conformal deposition process. Further, the pattern can be transferred successfully by depositing another planarizing film like an organic planarization layer (OPL) or any other organic gap filling material, performing chemical-mechanical planarization (CMP) followed by a short etch back to remove OPL overburden to expose a top of the cap material, etching the cap material at the top of the resist such that the OPL in between the deposited cap material protects the sidewall and bottom surface of the cap material, and removing EUV resist using any resist etch process which is selective to the high-k cap material. The cap material structure can thus be used as a mask to etch hard mask material of the tri-layer or quad-layer stack.

Examples of semiconductor materials that can be employed in forming such structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

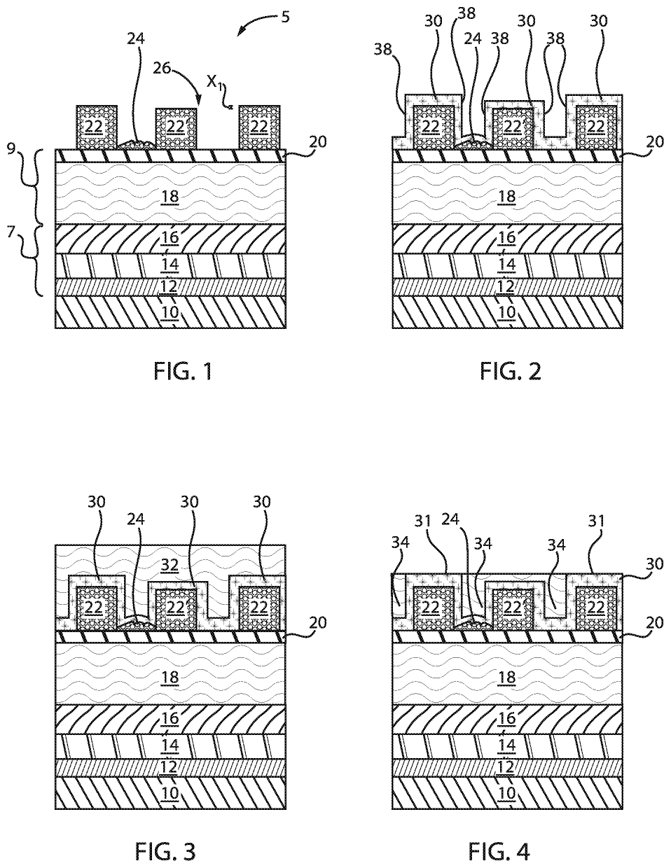

FIG. 1 is a cross-sectional view of a semiconductor structure illustrating photoresist portions experiencing resist scumming and local thinning, in accordance with an embodiment of the present invention.

The semiconductor stack 5 includes a hard mask 7 formed over a low-k dielectric or dielectric material layer 10, which in turn is formed over a substrate (not shown). The hard mask 7 can include a first dielectric layer 12, a metal film 14, and a second dielectric layer 16. Therefore, the hard mask 7 can be a metal, and/or a dielectric combination. The first dielectric layer 12 can be a nitride layer. The nitride layer can be, e.g., a silicon nitride (SiN) layer. The second dielectric layer 16 can be an oxide layer. The oxide layer can be, e.g., a silicon dioxide (SiO₂) layer.

The metal film 14 can be, e.g., a titanium nitride (TiN) film located directly between the first and second dielectric layers 12, 16. The metal film hard mask layer 14 can further include TiON, TaN, WN, BN, a combination thereof, or a stack thereof. The metallic layer or metal film 14 can be comprised of a metallic barrier material such as, for example, Co, TaN, Ta, Ti, TiN, Ru, Ir, Au, Rh, Pt, Pd or Ag. Alloys of such materials are also contemplated.

A lithographic stack 9 can be formed over the hard mask 7. The lithographic stack 9 includes an organic planarization layer (OPL) 18 and an anti-reflective coating (ARC) layer 20 forming tri-layer stack. In another embodiment, lithographic stack 9 includes an organic planarization layer (OPL) 18 and a layer 20 consisting of a dielectric hard mask film and an anti-reflective coating (ARC) forming quad-layer stack.

The dielectric material layer 10 can include a low-k dielectric material. The term “low-k” denotes a dielectric material having a dielectric constant that 4.0 or less. Exemplary low-k dielectric materials include, but are not limited to, silicon oxide, organosilicates, silsesquioxanes, undoped silicate glass (USG), fluorosilicate glass (FSG), borophosphosilicate glass (BPSG), and hydrogenated carbon doped silicon oxide (SiCOH). The dielectric material layer 10 can be formed by chemical vapor deposition (CVD), plasma enhanced chemical vapor deposition (PECVD) or spin coating. The thickness of the dielectric material layer 10 can be from about 100 nm to about 1,000 nm, although lesser and greater thicknesses can also be employed.

The substrate formed under the dielectric material layer 10 can be a silicon substrate, a germanium substrate, a silicon on oxide substrate, a silicon on insulator substrate, a III-V heterogeneous semiconductor such as GaAs, InP and etc., or any combination thereof.

The substrate thickness is not intended to be limited. In one aspect, the substrate is silicon-on-insulator (SOI) and has a thickness in a range from about 5 nanometers (nm) to about 100 nm. In another aspect, the substrate is bulk silicon (Si) and has a thickness in a range from about 700 micrometers (μm) to about 800 μm. Yet, in another aspect, the substrate has a thickness about or in any range from about 0.1, 0.5, 1, 100, 250, 500, and 750 μm.

The first dielectric layer 12 and the second dielectric layer 16 are different dielectric materials. The first and second dielectric layers 12, 16 can be any suitable oxide material, oxide precursor material, or nitride material. Non-limiting examples of suitable materials include tetraethyl orthosilicate (TEOS), silicon dioxide, silicon nitride, or any combination thereof.

The first and second dielectric layers 12, 16 can be formed by any suitable methods. Non-limiting examples of suitable methods for forming the first and second dielectric layers 12, 16 include physical vapor deposition (PVD), chemical vapor deposition (CVD), plasma-enhanced chemical vapor deposition (PECVD), atomic layer deposition (ALD), or any combination thereof.

The OPL layer 18 and the ARC layer 20 are used as a lithographic stack 9 to pattern the underlying layers. The OPL layer 18 is formed at a predetermined thickness to provide reflectivity and topography control during etching of the hard mask layers 7 below. The OPL layer 18 includes an organic material, such as a polymer. The thickness of the OPL layer 18 is in a range from about 50 nm to about 300 nm.

The layer 20 is an ARC layer which minimizes the light reflection during lithography for a tri-layer lithography stack. The ARC layer 20 can include silicon, for example, a silicon anti-reflective layer (SiARC). The thickness of the ARC layer 20 is in range from about 10 nm to about 100 nm. The anti-reflective film layer 20 can be an antireflective layer for suppressing unintended light reflection during photolithography. Exemplary materials for an antireflective layer include metal silicon nitrides, or a polymer film. The anti-reflective layer can be formed, depending on materials, for example, using sputter deposition, chemical vapor deposition, or spin coating.

In an embodiment, layer 20 is a bi-layer film where the bottom layer is a thin dielectric hard mask film and the top layer is an ARC layer forming a quad-layer lithography stack 9 along with OPL layer 18. Exemplary dielectric hard mask materials are silicon dioxide, silicon nitride, silicon carbide, silicon oxycarbide or any combination thereof. The hard mask film in layer 20 can be formed by any suitable methods. Non-limiting examples of suitable methods for forming the hard mask layer include physical vapor deposition (PVD), chemical vapor deposition (CVD), plasma-enhanced chemical vapor deposition (PECVD), atomic layer deposition (ALD) or any combination thereof. The thickness of the hard mask is in the range of about 1 nm to about 50 nm.

A photoresist 22 and 22′ can be formed over the layer 20. The photoresist 22 is in a non-damaged state, whereas the photoresist 22′ is in a damaged state. In other words, the photoresist 22′ has experienced resist thinning 26. The photoresist 22′ is shorter than the photoresists 22. The difference in height between photoresists 22 and 22′ is designated by “X₁.” Stated differently, the height of the photoresist 22′ is less than the height of the photoresists 22. Additionally, photoresist scumming can also be observed where photoresist residue 24 is formed between photoresist 22 and photoresist 22′.

The photoresist layer 22, 22′ includes a first pattern that is formed on the top surface of the layer 20. The photoresist layer can be formed, for example, by spin coating. The thickness of the photoresist layer can be from about 200 nm to about 600 nm, although lesser and greater thicknesses can also be employed. The photoresist layer can be a layer of a photoresist sensitive to deep-ultraviolet (DUV) radiation, extreme ultraviolet (EUV), or mid-ultraviolet (MUV) radiation as known in the art, or can be an e-beam resist that is sensitive to radiation of energetic electrons. In one preferred embodiment, the photoresist 22, 22′ is sensitive to EUV.

The photoresist layer 22, 22′ is lithographically patterned to form the pattern therein. The pattern can be a line pattern including multiple parallel lines that define mandrel structures subsequently formed. In one embodiment, the multiple parallel lines can have the same width and the same pitch. The width of the multiple parallel lines can be from about 10 nm to about 50 nm, although lesser and greater widths can also be employed. The pitch of the multiple parallel lines is a lithographic pitch, e.g., a pitch that can be printed by a single lithographic exposure employing a commercially available lithography tool and photoresist. In one embodiment, the pitch of the multiple parallel lines can be from about 50 nm to about 200 nm, although lesser and greater pitches can also be employed.

FIG. 2 is a cross-sectional view of the semiconductor structure of FIG. 1 where a conductive cap is deposited over the photoresist, in accordance with an embodiment of the present invention.

A conductive cap 30 is formed over the photoresist 22, 22′. The conductive cap 30 can include sidewalls 38. The conductive cap 30 is a metal cap. The metal cap can be, e.g., a high-k metal oxide or a high-k metal nitride. In one example, the metal cap 30 can be, e.g., TiN, TiOx, etc.

The conductive cap 30 can be formed by any suitable methods. Non-limiting examples of suitable methods for forming the conductive cap 30 include physical vapor deposition (PVD), chemical vapor deposition (CVD), plasma-enhanced chemical vapor deposition (PECVD), atomic layer deposition (ALD), or any combination thereof. In one preferred embodiment, the conductive cap 30 is formed by ALD. The conductive cap 30 can also be referred to as a thin etch resistant cap material. The conductive cap 30 encapsulates the EUV resist 22, 22′.

The conductive cap 30 can have a thickness of about 3-4 nm for a pitch of an EUV pattern being less than 30 nm. The deposition temperature can be from about 80° C. to about 150° C.

FIG. 3 is a cross-sectional view of the semiconductor structure of FIG. 2 where an organic gap fill material is deposited over the conductive cap, in accordance with an embodiment of the present invention.

An organic gap fill material 32 is then formed over the conductive cap 30. The organic gap fill material 32 can be, e.g., an organic planarization layer (OPL). The organic planarization layer 32 can be formed using an organic material. Organic layers which can be used are positive photoresist or polyimide. If photoresist is used it can be spin coated similar to a conventional photolithography step in integrated circuit manufacturing. Alternatively, an application can choose to use an inorganic planarization layer rather than an organic planarization layer such as spun glasses, for example, emulsified doped silicon dioxide.

Therefore, tone inversion is accomplished by employing the conductive cap 30 and the organic gap fill material 32. The methods include a thin conformal coating of the resist to enable tone inversion to address defects caused by both resist scumming and local resist thinning concurrently. Thus, multi-layer films 30, 32 are employed for tone inversion. The use of the thin film 30 prevents complete filling of recesses by the cap material in the region where resist thinning occurs. This helps eliminate line break defects during pattern transfer. Stated differently, an inverse patterning scheme can be employed for an organic resist-based patterning stack. As a result, the EUV resist pattern is inverted.

FIG. 4 is a cross-sectional view of the semiconductor structure of FIG. 3 where the organic gap fill material is recessed by a first amount to expose a top surface of the conductive cap where photoresist portions are affected by resist scumming and resist thinning, in accordance with an embodiment of the present invention.

The organic gap fill material 32 can be partially removed by a recess etch or a planarization process such as, for example, by chemical mechanical polishing (CMP). The CMP results in a top surface 31 of the conductive cap 30 being exposed. The top surface of the damaged photoresist 22′ is not exposed. In fact, a small portion of the of the organic gap fill material 32 remains over the damaged photoresist 22′. The remaining organic gap fill material is designated as 34.

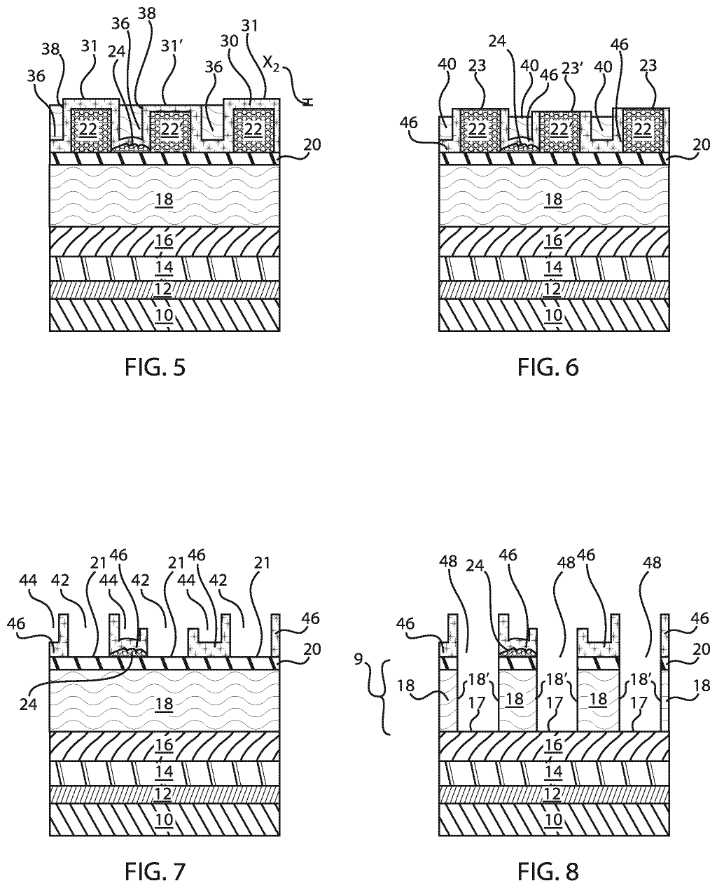

FIG. 5 is a cross-sectional view of the semiconductor structure of FIG. 4 where the organic gap fill material is recessed by a second amount to expose a top surface of the conductive cap of a photoresist portion experiencing local resist thinning, in accordance with an embodiment of the present invention.

CMP can be followed by a short etch back to remove the organic gap fill material overburden. In particular, the remaining organic gap fill material 34 is further recessed to expose a top surface 31′ of the conducive cap 30 formed over the damaged photoresist 22′. The remaining organic gap fill material is designated as 36. Additionally, a top portion or section of the sidewalls 38 of the conductive cap 30 formed over the photoresists 22 are now exposed. The recess can be designated by “X₂.” An exemplary etch back process of organic gap fill material includes reactive ion etch using oxygen containing plasma.

FIG. 6 is a cross-sectional view of the semiconductor structure of FIG. 5 where further etching results in top surfaces of the photoresist being exposed, in accordance with an embodiment of the present invention.

Portions of the conductive cap 30 are etched to expose a top surface 23 of the photoresists 22 and a top surface 23′ of the damaged photoresist 22′. Conductive cap sections 46 remain between the photoresists 22, 22′. The remaining conductive cap sections 46 can have a substantially U-shaped configuration. The remaining conductive cap sections 46 can hold remaining organic gap fill material 40. The remaining organic gap fill material 40 between the remaining conductive cap sections 46 protects the sidewalls and bottom surface of the cap material. An etch process for the conductive cap 30 can include a reactive ion etching process using chlorine and/or fluorine containing plasma.

FIG. 7 is a cross-sectional view of the semiconductor structure of FIG. 6 where the photoresist is removed, in accordance with an embodiment of the present invention.

The photoresist 22, 22′ is removed such that openings 42 are formed between the remaining conductive cap sections 46. The top surface 21 of the ARC layer 20 is now exposed. An example process of removing photoresist 22, 22′ includes reactive ion etch using oxygen containing plasma. Additionally, the remaining organic gap fill material 40 formed over the remaining conductive cap sections 46 is also removed during etching of photoresists 22, 22′ to form gaps 44 within the remaining conductive cap sections 46.

The pattern in the photoresist layer is transferred through the layer 20 and layer 18 by a pattern transfer etch, which can be an anisotropic etch. In one embodiment, the pattern transfer etch can be a reactive ion etch (RIE) that removes the materials of the layer 20 and the layer 18. The remaining portions of the layer 20 constitute the patterned ARC or ARC/hard mask layer. The remaining portions of the OPL 18 constitute the patterned OPL layer.

FIG. 8 is a cross-sectional view of the semiconductor structure of FIG. 7 where etching takes place between the remaining conductive cap sections to expose a top surface of a dielectric layer, in accordance with an embodiment of the present invention.

The lithographic stack 9 is etched to expose sidewalls 18′ of the OPL layer 18 and to expose a top surface 17 of the second dielectric layer 16 of the hard mask layers 7, as well as to cause openings or trenches 48 between the remaining conductive cap sections 46. This can be referred to as the mask etch process.

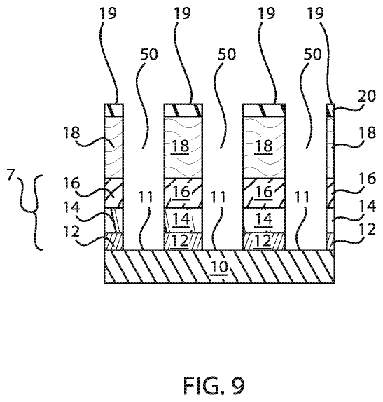

FIG. 9 is a cross-sectional view of the semiconductor structure of FIG. 8 where a pattern transfer occurs to underlying films, in accordance with an embodiment of the present invention.

The hard mask layer 7 is etched to expose a top surface 11 of the dielectric material layer 10, and openings or trenches 50 are formed into the lithographic stack 9 and the hard mask stack 7. Moreover, the remaining conductive cap sections 46, ARC layer 20, and the photoresist residue 24 are removed during hard mask layer 7 etch exposing a top surface 19 of the OPL layer 18. The remaining conductive cap sections 46 thus act as a mask to etch the tri-layer or quad-layer stacks.

The metal nitride hard mask layer 14 can be etched by an anisotropic etch. The anisotropic etch can be a dry etch or a wet chemical etch that removes the material of the metal nitride hard mask layer 14. In one embodiment, a chlorine-containing gas can be employed to etch the metal nitride hard mask layer 14. The remaining portions of the metal nitride hard mask layer constitute the patterned metal nitride hard mask layer.

Moreover, the pattern in the metal nitride hard mask layer 14 can be transferred into the underlying dielectric layer, e.g., the first dielectric hard mask layer 12. The remaining portions of the dielectric hard mask layer 12 constitute the patterned dielectric hard mask layer. After transferring the pattern into the underlying dielectric layer, the patterned metal nitride hard mask layer and the patterned dielectric hard mask layer can be removed by a recess etch or a planarization process such as, for example, by chemical mechanical polishing (CMP). Line trenches 50 can thus be formed. Subsequently, a conductive material layer (not shown) can be deposited in the line trenches 50 and planarized to provide interconnect structures (not shown).

In conclusion, a method is presented for eliminating patterning defects caused by resist scumming and local resist thinning while transferring an EUV resist pattern. A modified tone inversion method can be employed to eliminate patterning defects caused by both resist scumming and local resist thinning. A thin cap material and a bulk organic material can be employed to perform tone inversion (tone inversion using multi-layer films). The thin cap material is the etch resistant material that acts as a mask for pattern transfer after tone inversion. The etch resistant cap material can be, e.g., TiN or TiOx and can be deposited by using a conformal deposition method, such as, e.g., ALD.

It will be helpful in appreciating the effects of the invention in the following discussion to recall that selectivity of etching is generally a function of a difference in etch rates of different materials for a given etchant chemistry. Therefore, factors that tend to slow the etching of the selectively etched material tends to reduce effective selectivity to other materials and that best selectivity will be observed when the etch progresses as rapidly as possible.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which include multiple copies of the chip design in question that are to be formed on a wafer. The photolithographic masks are utilized to define areas of the wafer to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys. Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a method for transferring patterns effectively by using EUV resist to overcome limitations by resist thickness, resist scumming, and resist thinning (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A method for transferring patterns to underlying films in patterning stacks, the method comprising:
forming a lithographic stack over a hard mask stack;
forming a photoresist layer over the lithographic stack;
depositing a conductive cap over the photoresist layer;
depositing an organic gap filling material over the conductive cap;
recessing the organic gap filling material to expose top surfaces of the conductive cap;
etching the exposed top surfaces of the conductive cap to expose top surfaces of the photoresist layer;
removing the photoresist layer such that substantially U-shaped conductive cap sections remain over the lithographic stack, the removing of the photoresist layer resulting in removal of remaining organic gap filling material confined within the substantially U-shaped conductive cap sections; and
forming trenches into the lithographic stack and the hard mask stack by using the conductive cap sections as a mask.

2. The method of claim 1, wherein the lithographic stack includes two layers for a tri-layer stack or three layers for a quad-layer stack.

3. The method of claim 2, wherein the two layers in the tri-layer lithographic stack are an organic planarization layer and an anti-reflective coating layer, and the three layers in the quad-layer stack are an organic planarization layer, a dielectric hard mask, and an anti-reflective coating layer.

4. The method of claim 3, wherein the hard mask stack includes three layers.

5. The method of claim 4, wherein the three layers are a first dielectric layer, a second dielectric layer, and a metal layer formed directly between the first and second dielectric layers.

6. The method of claim 1, wherein the conductive cap is a high-k metal oxide or nitride film.

7. The method of claim 1, wherein the conductive cap is a titanium nitride (TiN) cap.

8. The method of claim 1, wherein the organic gap filling material is an organic planarization layer (OPL).

9. The method of claim 1, wherein tone inversion is performed by a combination of the conductive cap and the organic gap filling material.

10. A method for eliminating patterning defects caused by resist scumming and resist thinning while transferring an extreme ultraviolet (EUV) resist pattern, the method comprising:
forming a photoresist layer over a lithographic stack and a hard mask stack;
performing tone inversion by depositing a conductive cap and an organic gap filling material over the photoresist layer;
recessing the organic gap filling material to expose top surfaces of the conductive cap;
etching the exposed top surfaces of the conductive cap;
removing the photoresist layer such that substantially U-shaped conductive cap sections remain over the lithographic stack, the removing of the photoresist layer resulting in removal of remaining organic gap filling material confined within the substantially U-shaped conductive cap sections; and
using the substantially U-shaped conductive cap sections as a mask to form trenches into the lithographic stack and the hard mask stack.

11. The method of claim 10, wherein the lithographic stack includes two layers for a tri-layer stack or three layers for a quad-layer stack.

12. The method of claim 11, wherein the two layers in the tri-layer lithographic stack are an organic planarization layer and an anti-reflective coating layer, and the three layers in the quad-layer stack are an organic planarization layer, a dielectric hard mask, and an anti-reflective coating layer.

13. The method of claim 12, wherein the hard mask stack includes three layers.

14. The method of claim 13, wherein the three layers are a first dielectric layer, a second dielectric layer, and a metal layer formed directly between the first and second dielectric layers.

15. The method of claim 10, wherein the conductive cap is a high-k metal oxide or nitride film.

16. The method of claim 10, wherein the conductive cap is a titanium nitride (TiN) cap.

17. The method of claim 10, wherein the organic gap filling material is an organic planarization layer (OPL).

18. A method for eliminating patterning defects caused by resist scumming and resist thinning while transferring an extreme ultraviolet (EUV) resist pattern, the method comprising:
forming an organic planarization layer;
forming an anti-reflective coating layer over the organic planarization layer;
forming a photoresist layer over the anti-reflective coating layer;
performing tone inversion by depositing a conductive cap and an organic gap filling material over the photoresist layer;
etching exposed top surfaces of the conductive cap after recessing the organic gap filling material;
removing the photoresist layer such that substantially U-shaped conductive cap sections remain, the removing of the photoresist layer resulting in removal of remaining organic gap filling material confined within the substantially U-shaped conductive cap sections; and
using remaining substantially U-shaped conductive cap sections as a mask to form trenches into at least the anti-reflective coating layer and the organic planarization layer.

19. The method of claim 18, wherein the organic planarization layer is formed over a hard mask stack.

20. The method of claim 19, wherein the hard mask stack includes a first dielectric layer, a second dielectric layer, and a metal layer formed directly between the first and second dielectric layers.
